(19) United States
(12) Patent Application Publication
(10) Pub. No.: US 2010/0006145 A1
(43) Pub. Date: Jan. 14, 2010

(54) SOLAR CELL AND FABRICATING METHOD FOR THE SAME

(75) Inventor: Sang In LEE, Sunnyvale, CA (US)

Correspondence Address: FENWICK & WEST LLP, SILICON VALLEY CENTER, 801 CALIFORNIA STREET, MOUNTAIN VIEW, CA, 94041, US

(73) Assignee: SYNOS TECHNOLOGY, INC., Synnyvale, CA (US)

(21) Appl. No.: 12/498,298

(22) Filed: Jul. 6, 2009

(30) Foreign Application Priority Data
Jul. 8, 2008 (KR) 10-2008-0066260

(51) Int. Cl. H01L 31/00; H01L 31/18

(52) U.S. Cl. 136/255; 136/256; 438/73; 257/E21.158

(57) ABSTRACT

Example embodiments relate to a solar cell and a method for fabricating the same, and more particularly, to a solar cell in which a substrate capable of functioning as electrode is used and a method for fabricating the same. The solar cell may include a substrate and a semiconductor layer laminated on the substrate. The solar cell may include a conductive substrate. The substrate may be a flexible substrate having a coefficient of thermal expansion comparable to that of the semiconductor layer. The semiconductor layer may be formed on the substrate. The solar cell may include a front electrode formed on the semiconductor layer.

### CROSS-REFERENCE TO RELATED APPLICATION

This application claims priority under 35 U.S.C. §119(a) to Republic of Korea Patent Application No. 10-2008-0066260, filed on Jul. 8, 2008, with the Korean Intellectual Property Office (KIPO), the entire contents of which are incorporated herein by reference.

### BACKGROUND

1. Field

Example embodiments relate to a solar cell and a method for fabricating the same, and more particularly, to a solar cell in which a substrate capable of functioning as electrode is used and a method for fabricating the same.

2. Description of the Related Art

A solar cell may be manufactured to be flexible by using a flexible substrate having a coefficient of thermal expansion comparable to that of a semiconductor layer of a solar cell. When silicon (Si) or compound semiconductors are used as the semiconductor layer of the solar cell, a flexible substrate may have a coefficient of thermal expansion of about 2 to 12×10⁻⁶/K.

In addition to the coefficient of thermal expansion requirement, a flexible substrate may satisfy the various requirements including the followings. 1) It should be without outgassing during deposition in vacuum state. 2) It should endure a temperate of at least about 350° C. so as to be thermally stable during the following deposition or heat treatment processes. 3) It should not experience corrosion during processing. 4) It should be insusceptible to corrosion or degradation in the course of use of a solar cell (normally 25 years) and be resistant to penetration of moisture. 5) The surface of the substrate should be smooth. 6) The substrate should be light and inexpensive.

Flexible substrate materials satisfying these requirements may include soda-lime glass, Corning 7059 glass, aluminum (Al), titanium (Ti) and silica (SiO₂, fused quartz). Although these materials satisfy the aforesaid coefficient of thermal expansion requirement, soda-lime glass requires a diffusion barrier layer so as to prevent the diffusion of impurities included therein, e.g., sodium (Na), potassium (K). Although Corning 7059 glass does not include alkali components, a diffusion barrier layer is required to prevent penetration of moisture. And, titanium, silica, alumina, etc. are expensive. Further, aluminum is not adequate for use as flexible substrate because the coefficient of thermal expansion is very high as 23 to 24×10⁻⁶/K.

### SUMMARY

Example embodiments provide a solar cell in which a substrate capable of functioning as electrode is used, and a method for fabricating the same.

Example embodiments also provide a solar cell in which a silicide layer, a diffusion barrier layer, a BSF (back surface field) layer, an infrared (IR) reflecting layer, etc. is optionally used so as to provide optimized energy conversion efficiency, and a method for fabricating the same.

In an aspect, a solar cell may include: a substrate; a semiconductor layer formed on the substrate; and a front electrode formed on the semiconductor layer.

The substrate may be a flexible substrate having a coefficient of thermal expansion comparable to that of the semiconductor layer. Further, the substrate may function as a back electrode and may be formed of a graphite substrate and a chrome steel substrate. Furthermore, a silicide layer may be provided between the substrate and the semiconductor layer, a first diffusion barrier layer may be provided between the substrate and the silicide layer, and a second diffusion barrier layer may be provided between the silicide layer and the semiconductor layer.

The semiconductor layer may include a p-type semiconductor layer and an n-type semiconductor layer, or a n-type semiconductor layer and an p-type semiconductor layer. Or, a highly concentrated p-type semiconductor layer including a relatively higher concentration of a p-type dopant than that of the p-type semiconductor layer may be further provided below the p-type semiconductor layer.

A transparent electrode may be further provided between the semiconductor layer and the front electrode. In order to enhance electric conductivity of the transparent electrode, a dopant may be doped into the transparent electrode or the first transparent electrode and the second transparent electrode may be laminated alternatively and repeatedly.

The first transparent electrode may be made of a material selected from ZnO, NiO, SnO₂, ITO (indium tin oxide), GZO (gallium zinc oxide), IGZO (indium gallium zinc oxide), IGO (indium gallium oxide), IZO (indium zinc oxide) and In₂O₃. The second transparent electrode may be made of a group III-V compound, such as AlN, GaN and InN. Further, the first transparent electrode may be doped with a dopant selected from Al, In, Ga and a combination thereof, at a content of 0.1 to 10%.

An IR barrier layer may be provided on at least one of the top and bottom portions of the transparent electrode, and the transparent electrode and the IR barrier layer may be laminated alternatively. Further, a protective layer may be further provided on the front electrode, and an alumina layer may be further provided between the front electrode and the protective layer.

The silicide layer may be made of any one selected from NiSi₂, TiSi₂, CoSi₂, MoSi₂, PdSi₂, PtSi₂, TaSi₂ and WSi₂. The first diffusion barrier layer may include a refractory metal nitride layer which is selected from TiN, TaN and WN, or a refractory metal/refractory metal nitride double layer in which a refractory metal which is selected from Ti, Ta, Mo, Co, and Ni, and a refractory metal nitride which is selected from TiN, TaN, WN and MoN are sequentially laminated. The second diffusion barrier layer may be made of any oxide selected from SiO₂, NiO, Al₂O₃, AgO, CuO, ZnO, In₂O₃, SnO₂, InSnO_{X}, TiO₂, HfO₂, ZrO₂, RuO₂ and Ta₂O₅, or a metal-silicate formed by atomic layer deposition. Further, the transparent electrode may be made of any one selected from ZnO, NiO, SnO₂, ITO, GZO, IGZO, IGO, IZO and In₂O₃, the IR barrier layer may be made of any one selected from Al, Au, Ag, Ru, Ir, Pt, Ni, Co, Ti, Ta and Cu. The protective layer may be made of SiNₓ, AlN, SiO₂, NiO, Cr₂O₃, Al₂O₃ or a combination thereof.

The substrate may have a thickness of 0.005 to 0.125 inch. The semiconductor layer may be made of Si, SiGe, a group III-V compound semiconductor, a group II-VI compound semiconductor or a combination thereof.

A method for fabricating a solar cell may include: (a) providing a substrate; (b) forming a semiconductor layer on the substrate; and (c) forming a front electrode on the semiconductor layer.

A step of: (a)-2 forming a silicide layer on the substrate may be further included prior to the step (b). A step of: (a)-1 forming a first diffusion barrier layer on the substrate may be further included prior to the step (a)-2. A step of: (a)-3 forming a second diffusion barrier layer on the silicide layer may be further included prior to the step (b). The step (b) may include a first process of forming a p-type semiconductor layer and a second process of forming an n-type semiconductor layer, wherein either of the first process or the second process may be carried out first.

The step (b) may further include forming a highly concentrated p-type semiconductor layer including a relatively higher concentration of a p-type dopant than that of the p-type semiconductor layer prior to forming the p-type semiconductor layer. The first transparent electrode may be doped with a dopant selected from, for example, Al, In, Ga and a combination thereof, at a content of 0.1 to 10%.

A step of: (b)-1 forming a transparent electrode on the semiconductor layer may be further included prior to the step (c), and in the step (b)-1, the transparent electrode and an IR barrier layer which is provided on at least one of the top and bottom portions of the transparent electrode may be laminated alternatively

The step (b)-1 may include either forming a first transparent electrode on the semiconductor layer or a combination of forming a first transparent electrode on the semiconductor layer and forming a second transparent electrode on the first transparent electrode. The first transparent electrode may be made of any one selected from ZnO, NiO, SnO₂, ITO, GZO, IGZO, IGO, IZO and In₂O₃, and the second transparent electrode may be made of a group III-V compound such as AlN, GaN and InN.

The first transparent electrode and the second transparent electrode may be formed by atomic layer deposition. The first transparent electrode may be doped with a dopant selected from Al, In, Ga and a combination thereof, at a content of 0.1 to 10%.

A step of: (c)-2 forming a protective layer on the front electrode may be further included following the step (c), and a step of: (c)-1 forming a metal oxide layer made of any one selected from Al₂O₃, NiO and TiO₂ on the front electrode may be further included prior to the step (c)-2. The step (a)-2 may include: depositing a metallic layer formed by atomic layer deposition on the substrate; and depositing silicon on the metallic layer to form a polycrystalline silicide layer comprising a metal-silicon combination. Further, the step (a)-2 may include: depositing a metallic layer formed by atomic layer deposition on the substrate; and depositing a semiconductor material of any one of Si and SiGe on the metallic layer to form a polycrystalline semiconductor layer comprising a metal-semiconductor combination.

The solar cell according to an example embodiment may provide the following advantageous effects.

Since a flexible substrate having a coefficient of thermal expansion comparable to that of a semiconductor layer, e.g., a graphite substrate or a chrome steel substrate, may be used, a flexible solar cell may be fabricated easily. Further, the graphite substrate or the chrome steel substrate may not only serve as a substrate but also function as a back electrode. Consequently, the use of an aluminum back electrode may be unnecessary, and the manufacturing process may be simplified and the manufacturing cost may be reduced.

### BRIEF DESCRIPTION OF THE DRAWINGS

The above and other objects, features and other advantages of the present invention will be more clearly understood from the following detailed description taken in conjunction with the accompanying claims.

FIG. 1 is an exploded perspective view of a solar cell according to an example embodiment.

FIG. 2 is an exploded perspective view of a solar cell according to an example embodiment, which further comprises a first diffusion barrier layer.

FIG. 3 is an exploded perspective view of a solar cell according to an example embodiment, which further comprises a highly concentrated p-type semiconductor layer (p⁺).

FIG. 4 is an exploded perspective view of a solar cell according to an example embodiment, which further comprises a second diffusion barrier layer.

FIG. 5A, FIG. 5B, and FIG. 5C are drawings illustrating a solar cell according to an example embodiment, which further comprises an IR barrier layer.

FIG. 6 is an exploded perspective view of a solar cell according to an example embodiment, which further comprises an alumina layer.

FIG. 7 is a flowchart for illustrating a method for fabricating a solar cell according to an example embodiment.

### DETAILED DESCRIPTION OF EXAMPLE EMBODIMENTS

Hereinafter, reference will be made in detail to various example embodiments of a solar cell and a method for fabricating the same, which are illustrated in the accompanying drawings and described below. While the invention will be described in conjunction with example embodiments, it will be understood that the present description is not intended to limit the invention to those example embodiments. On the contrary, the invention is intended to cover not only the example embodiments, but also various alternatives, modifications, equivalents and other embodiments, which may be included within the spirit and scope of the invention as defined in the appended claims.

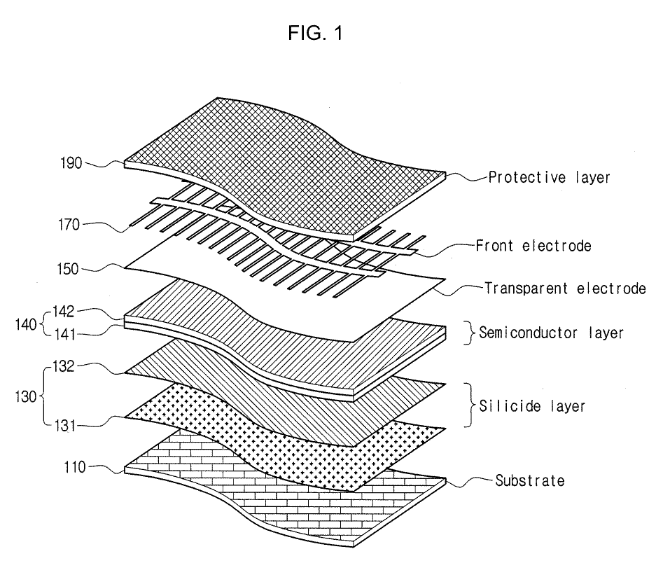

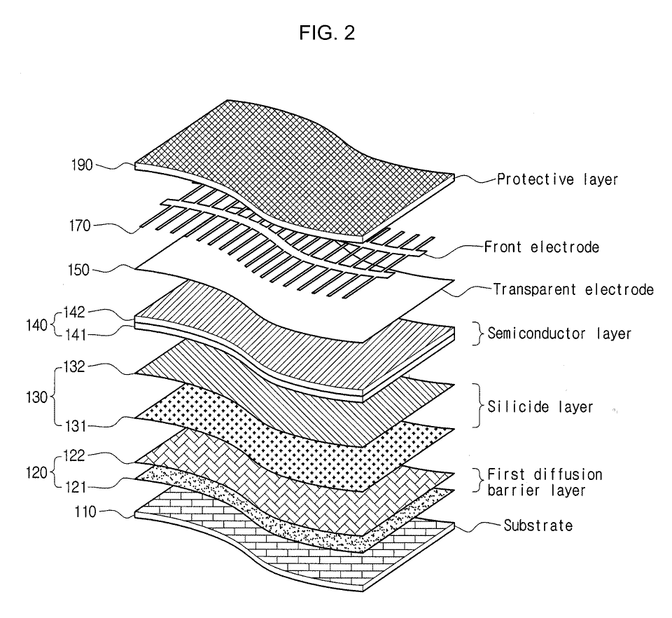

FIG. 1 is an exploded perspective view of a solar cell according to an example embodiment, and FIG. 2 through FIG. 6 are exploded perspective views of solar cells, which further comprise a first diffusion barrier layer, a highly concentrated p-type semiconductor layer (p⁺), a second diffusion barrier layer, an IR barrier layer and an alumina layer, respectively.

As illustrated in FIG. 1, a solar cell according to an example embodiment may comprise a substrate 110, and a polycrystalline silicide layer 130, a polycrystalline semiconductor layer 140, a transparent electrode 150, a front electrode 170 and a protective layer 190 may be sequentially laminated on the substrate 110.

The substrate 110 may be formed of a graphite substrate (graphite foil) or a chrome steel substrate (chrome steel foil). In that case, the graphite substrate or the chrome steel substrate may not only serve as a substrate but also function as a back electrode, which is normally provided at the back side of the substrate. Typically, a back electrode made of aluminum (Al) may be provided at the back side of the substrate. However, since the graphite substrate or the chrome steel substrate may function as a back electrode, it may not be necessary to provide an additional aluminum electrode.

Further, the substrate 110 may be a flexible substrate. For example, the substrate 110 may have a coefficient of thermal expansion comparable to that of the semiconductor layer 140.

The polycrystalline silicide layer 130 may serve to reduce contact resistance between the substrate 110 and the semiconductor layer 140. The polycrystalline silicide layer may be formed of any one of NiSi₂, TiSi₂, CoSi₂, MoSi₂, PdSi₂, PtSi₂, TaSi₂ and WSi₂. NiSi₂ may be used for the silicide layer 130 over other silicides, because it is associated with low silicide formation temperature, less diffusion into silicon (Si) and less consumption of silicon.

The polycrystalline silicide layer 130 may be formed by laminating a metallic layer 131 and then depositing a silicon layer 132. In the process of laminating the metallic layer 131, the metallic layer 131 should be adsorbed well to the substrate 110, i.e., the graphite substrate or the chrome steel substrate. In order to improve adsorption property of the metallic layer 131 as well as to prevent carbon (C), in case of the graphite substrate, or chromium (Cr), nickel (Ni), etc., in case of the chrome steel substrate, from diffusing into the semiconductor layer 140, a first diffusion barrier layer 120 may be further provided on the substrate 110, as illustrated in FIG. 2. The first diffusion barrier layer 120 may be formed of a refractory metal nitride layer 122 which is selected from TiN, TaN and WN. Alternatively, the first diffusion barrier layer 120 may be formed of a refractory metal/refractory metal nitride double layer 121 and 122 in which a refractory metal which is selected from Ti, Ta, Mo, Co and Ni, and a refractory metal nitride which is selected from TiN, TaN, WN and MoN are sequentially laminated.

Next, the polycrystalline semiconductor layer 140 may comprise a p-type semiconductor layer 141 and an n-type semiconductor layer 142. When light is incident on a p-n junction of the p-type semiconductor layer 141 and the n-type semiconductor layer 142, electrons and holes may be generated due to light energy at the p-type semiconductor layer 141 and the n-type semiconductor layer 142, respectively. Thus produced electrons and holes may result in electric current, which may be utilized as power source. The p-type semiconductor layer 141 and the n-type semiconductor layer 142 may be formed of any one of polycrystalline Si or a compound semiconductor such as SiGe, GaAs, CdTe, CdS and Cu(In,Ga)Se. They may be prepared by doping a p-type dopant or an n-type dopant into these materials. The p-type semiconductor layer 141 and the n-type semiconductor layer 142 may be laminated in sequence to form a p-type/n-type semiconductor layer 141 and 142 or an n-type/p-type semiconductor layer 142 and 141. These semiconductor layers may be laminated repeatedly.

Further, an intrinsic semiconductor layer (not shown) may be provided between the p-type semiconductor layer 141 and the n-type semiconductor layer 142. The intrinsic semiconductor layer may be formed of the same material constituting the p-type semiconductor layer 141 or the n-type semiconductor layer 142, but the intrinsic semiconductor layer may not be doped with dopants.

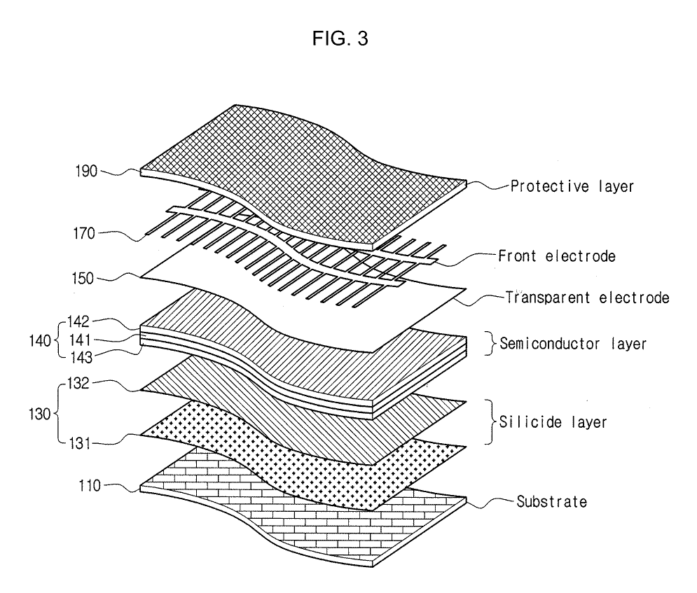

Further, a p-type semiconductor layer 143 (p⁺) in which a highly concentrated p-type dopant is doped may be provided below the p-type semiconductor layer 141, as illustrated in FIG. 3. The highly concentrated p-type semiconductor layer 143 (p⁺) may serve to provide a back surface field (BSF), and may be formed of the same material constituting the p-type semiconductor layer 141 or the n-type semiconductor layer 142.

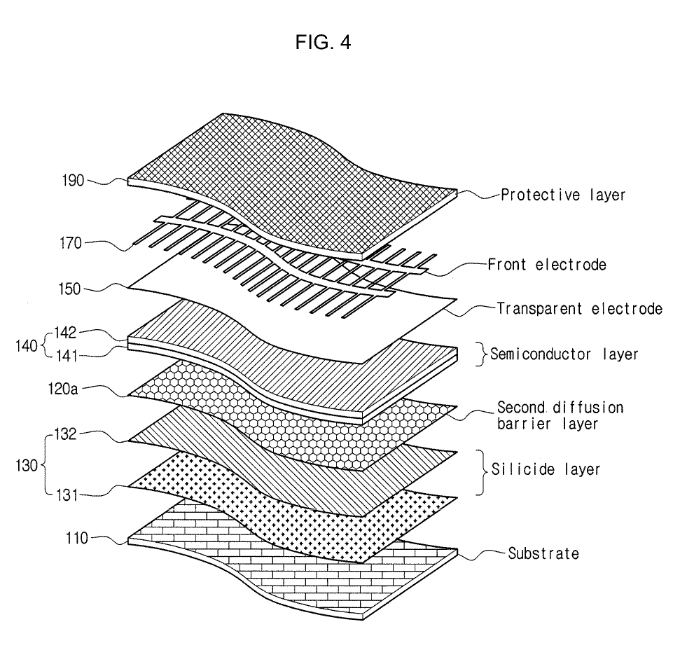

During the formation of the semiconductor layer 140, the metal constituting the silicide layer 130 may be diffused into the semiconductor layer 140. In order to prevent this, a second diffusion barrier layer 120a may be further provided between the silicide layer 130 and the semiconductor layer 140, as illustrated in FIG. 4. The second diffusion barrier layer 120a may be formed of any oxide selected from SiO₂, NiO, Al₂O₃, AgO, CuO, ZnO, In₂O₃, SnO₂, InSnO_{X}, TiO₂, HfO₂, ZrO₂, RuO₂ and Ta₂O₅. Alternatively, the second diffusion barrier layer 102a may be formed of a metal-silicate formed by atomic layer deposition, such as HfSiOx, ZrOx, NiSiOx, TiSiOx, CoSiOx or MoSiO.

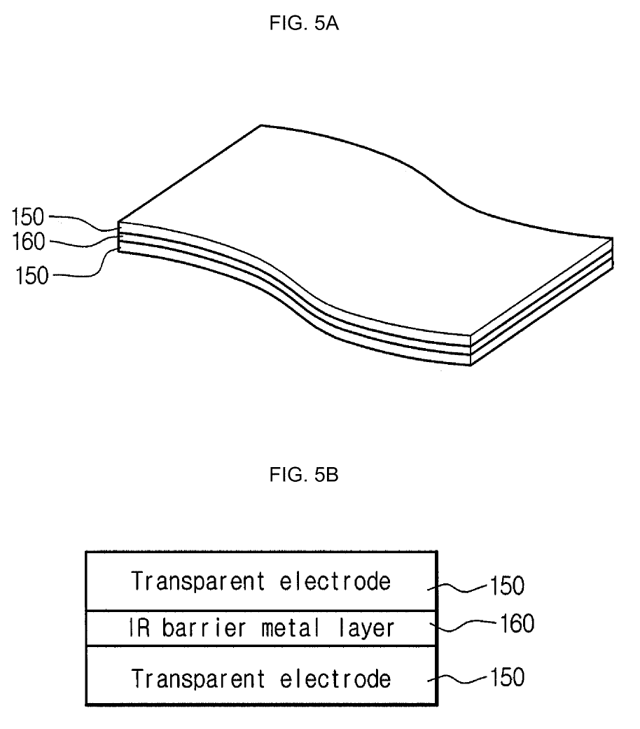

Next, the transparent electrode 150 (TCO: transparent conductive oxide) may be formed of ZnO, NiO, SnO₂, ITO (indium tin oxide), GZO (gallium zinc oxide), IGZO (indium gallium zinc oxide), IGO (indium gallium oxide), IZO (indium zinc oxide), In₂O₃, etc. In order to improve conductivity of the transparent electrode 150 as well as reflect IR, which may induce the temperature increase of the substrate 110, an IR reflecting layer 160 may be provided along with the transparent electrode 150. Specifically, a structure of IR reflecting layer 160/transparent electrode 150/IR reflecting layer 160 or transparent electrode 150/IR reflecting layer 160/transparent electrode 150 may be employed, as illustrated in FIG. 5A, FIG. 5B, and FIG. 5C. The IR reflecting layer may be formed of any one of Al, Au, Ag, Ru, Ir, Pt, Ni, Co, Ti, Ta and Cu.

Next, the front electrode 170 may serve to induce the movement of the carriers generated in the p-type semiconductor layer 141 or the n-type semiconductor layer 142, and may be formed to have a comb-shaped structure. As described earlier, a back electrode may be normally provided at the back side of the substrate. However, an example embodiment may not require a comb-shaped electrode below the substrate 110, because the substrate 110, i.e., the graphite substrate or the chrome steel substrate may also function as the back electrode. Still, a conductive pattern (not illustrated) may be provided for connection with an external wiring.

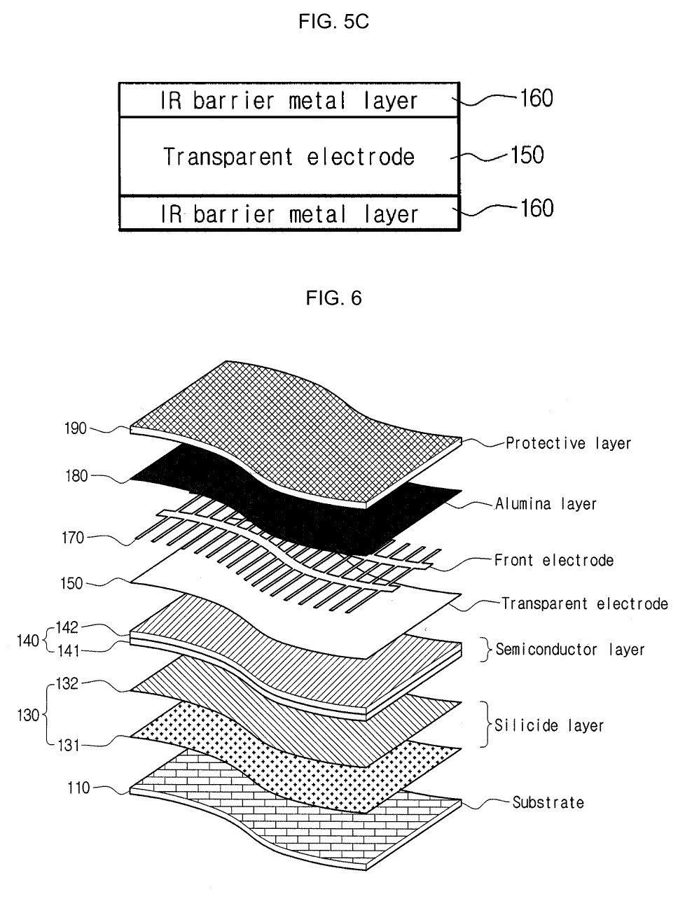

Lastly, the protective layer 190 provided on the front electrode 170 may serve to protect the solar cell from external physical or chemical impact and to enhance light absorption. The protective layer 190 may be formed of SiNₓ, AlN, SiO₂, NiO, Cr₂O₃, Al₂O₃ or a combination thereof. An alumina (Al₂O₃) layer 180 may be further provided between the front electrode 170 and the protective layer 190 in order to prevent deterioration of the transparent electrode 150, as illustrated in FIG. 6.

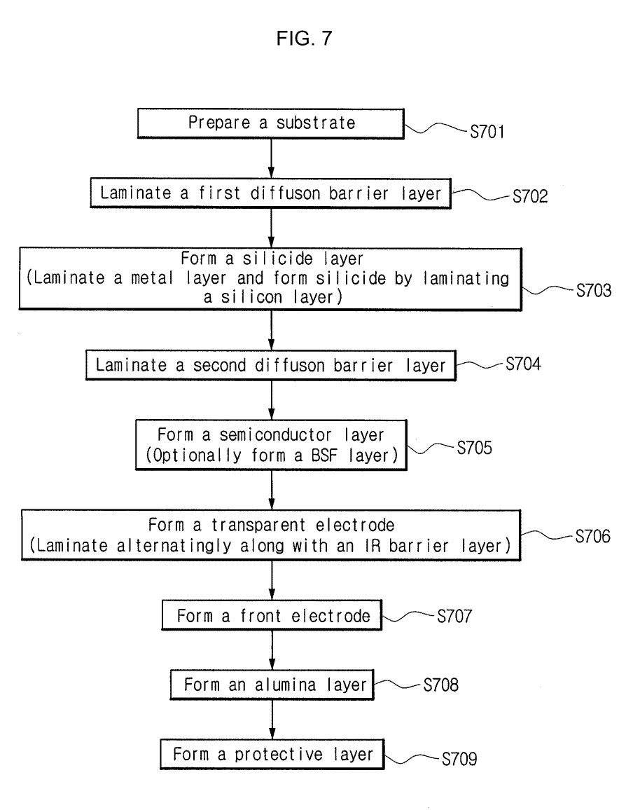

The construction of the solar cell according to an example embodiment was described above. Now, a method for fabricating a solar cell according to an example embodiment will be described. FIG. 7 is a flowchart for illustrating a method for fabricating a solar cell according to an example embodiment.

First, a substrate 110 may be prepared (S701) (see FIG. 1). The substrate 110 may be a flexible substrate. For example, the substrate 110 may be a graphite substrate (graphite foil) or a chrome steel substrate (chrome steel foil). For the convenience of illustration, a description will be given for a graphite substrate hereinafter. A graphite substrate may have a coefficient of linear thermal expansion of about 2×10⁻⁶/K along the horizontal direction, and a coefficient of linear thermal expansion of about 5×10⁻⁶/K along the vertical direction, which are comparable to those of the silicon-based semiconductor layer 140 or a compound semiconductor. The graphite substrate may have a relatively good resistivity of 600 to 800 μΩ·cm. And, a chrome steel substrate may have a coefficient of thermal expansion of about 10×10⁻⁶/K and a high electric conductivity. Although it is possible that chromium, nickel, etc. inside the chrome steel substrate may diffuse into other layers, a first diffusion barrier layer 120 may be provided to solve the problem, as described above.

As the graphite substrate or the chrome steel substrate may be used as the substrate, the substrate may not only serve as a substrate but also function as a conductor. In an example embodiment, the substrate may not only serve as a substrate, but also function as a back electrode. In an example embodiment, a graphite foil having a thickness of 0.127 mm (0.005 inch) and a carbon content of 99.5% or more (S: 200 ppm, Cl: 20 ppm) may be used as the graphite substrate. A much less thickness (0.05 mm) may be acceptable when a chrome steel substrate is used. The graphite substrate may have a thickness of 0.005 to 0.125 inch. For reference, Si and Si—Ge (0<Ge<85%) may have coefficients of thermal expansion of 2.6×10⁻⁶/K and 2.6 to 3.9×10⁻⁶/K, respectively. And, compound semiconductors GaAs, CdTe and Cu(In,Ga)Se may have coefficients of thermal expansion of 5.73×10⁻⁵/K, 5.9×10⁻⁶/K and ˜9×10⁻⁶/K, respectively.

After the substrate 110, that is, the graphite substrate, is prepared, wet cleaning using, for example, sulfuric acid (H₂SO₄) or dry cleaning using, for example, argon plasma may be carried out in order to remove organic contaminants such as organic materials and hydrocarbons (CHₓ) that may present on the surface of the graphite substrate. In case of a chrome steel substrate, dry cleaning may be carried out using argon plasma.

Subsequently, a silicide layer 130 may be formed (S703). The process of forming the silicide layer 130 may comprise depositing a metallic layer 131 (nucleation layer) and forming polycrystalline silicide by depositing a silicon layer 132. First, the metallic layer 131 may be deposited as follows. On the graphite substrate (or the chrome steel substrate), a polycrystalline metallic layer 131 may be deposited with a thickness of 1 to 300 Å. In an example embodiment, the metallic layer 131 may be deposited by plasma-enhanced atomic layer deposition (PEALD).

Specific conditions may be as follows. Bis(dimethylamino-2-methyl-2-butoxo)nickel (Ni(dmamb)2) may be supplied as precursor for 1 to 10 seconds. Hydrogen (H₂) plasma may be created at a power of 100 W to 1 kW, at a frequency of 13.56 MHz. The metallic layer 131 may be deposited at 250° C. by purging with argon for 1 to 10 seconds at a deposition rate of 0.9 Å/cycle. The metallic layer 131 may be formed of any one of Ni, Al, Ti, Co, Mo, Pd, Pt, Ta, W, AlOx, NiOx, CoOx, TiOx, TaOx, NiSi, TiSi, CoSi, MoSi, PdSi, PtSi, TaSi and WSi. Ni may be suitable considering low temperature processing, diffusion into silicon, or the like.

After the metallic layer 131 is deposited on the graphite substrate, a silicon layer 132 may be deposited to form a polycrystalline silicide layer 130 by inducing solid-phase reaction between the metal and silicon. Specifically, SiH₄ may be pyrolyzed at 400 to 900° C. to form a silicon layer 132 having a thickness of 1 to 500 Å. When the deposition is performed using plasma (e.g., hydrogen plasma), a silicon layer may be formed by pyrolysis at a relatively lower temperature. During the process of forming the silicon layer 132, the solid-phase reaction between the metal (Ni) and silicon (Si) may occur as they are diffused into each other, thereby forming the silicide layer (NiSi₂) 130. Heat treatment may be further carried out to stabilize the silicide. For instance, heat treatment may be carried out for 30 minutes above 300° C., for example at 450° C., under inert gas atmosphere. Or, when a halogen lamp heater is used, heat treatment may be carried out at 600 to 900° C. for 10 to 120 seconds. Although the pyrolysis of SiH₄ was presented as an example of forming the silicon layer 132, the silicon layer 132 may be formed by coating (spraying) silicon particles with a size of 100 nm to 5 μm using hydrogen plasma. Further, the silicon layer may be formed using a silicon-containing inorganic precursor such as Si₂H₆, Si₃H₈, etc. or a metal organic precursor such as TEMASi (tetraethylmethylaminosilicon; ((C₂H₅)(CH₃)N)₄Si), etc with hydrogen plasma. The silicon layer 132 may be formed through other suitable methods.

During the formation of the silicide layer 130, carbon ingredients of the graphite substrate may diffuse into the metallic layer 131 or the silicon layer 132. To prevent the diffusion of the carbon ingredients (metal atoms such as chromium, nickel, etc. in case of the chrome steel substrate), a first diffusion barrier layer 120 may be formed on the graphite substrate with a thickness of 10 to 500 Å prior to the formation of the silicide layer 130 (S702) (see FIG. 2). The first diffusion barrier layer 120 may be formed of either a refractory metal/refractory metal nitride double layer (e.g. Ti/TiN double layer) or a single refractory metal nitride layer (e.g. single TiN layer). In case the first diffusion barrier layer 120 is formed as a single TiN layer, TiN may be formed at 300 to 500° C. by supplying TiCl₄ and NH₃ as precursor for 1 to 10 seconds and then carrying out purging using argon gas. And, in case the first diffusion barrier layer 120 is formed as a Ti/TiN double layer, a Ti layer 121 may be formed at 450 to 600° C. using hydrogen plasma, using a high-frequency power supply with a power of 100 W to 1 kW and a frequency of 400 kHz, and then a TiN layer 122 may be formed continuously to form a Ti/TiN double layer 121 and 122.

Further, the process of forming the silicide layer 130 may include depositing the metallic layer 131 formed by atomic layer deposition on the substrate, and depositing a semiconductor material of any one of Si and SiGe on the metallic layer 131 to form a polycrystalline semiconductor layer comprising a metal-semiconductor combination.

After the silicide layer 130 is formed, a polycrystalline p-type semiconductor layer 141 and a polycrystalline n-type semiconductor layer 142 may be sequentially laminated to form a semiconductor layer 140 (S705). For reference, the order of lamination of the p-type semiconductor layer 141 and the n-type semiconductor layer 142 may be reversed. The p-type semiconductor layer 141 and the n-type semiconductor layer 142 may be formed of any one of Si, SiGe, a group III-V compound semiconductor and a group II-VI compound semiconductor. For instance, when Si is used, the p-type semiconductor layer 141 and the n-type semiconductor layer 142 may be formed by PE-CVD using SiH₄, pyrolysis of SiH₄ at 400 to 900° C., coating (spraying) of silicon particles with a size of 100 nm to 5 μm using hydrogen plasma, or the like. Each of the p-type semiconductor layer 141 and the n-type semiconductor layer 142 may be formed to have a thickness of 1 to 10 μm. A p-type dopant and an n-type dopant may be doped into the p-type semiconductor layer 141 and the n-type semiconductor layer 142, respectively. For the p-type dopant, B₂H₆ or Al may be doped at a concentration of 10¹⁵ to 1×10¹⁹/cm³, and for the n-type dopant, PH₃ or As may be doped at a concentration of 10¹⁵ to 1×10¹⁹/cm³.

Further, an intrinsic semiconductor layer (now shown) may also be formed between the p-type semiconductor layer 141 and the n-type semiconductor layer 142. The intrinsic semiconductor layer may be formed of the same material constituting the p-type semiconductor layer 141 or the n-type semiconductor layer 142, but the intrinsic semiconductor layer may not be doped with dopants.

Prior to the formation of the p-type semiconductor layer 141, a highly doped p-type semiconductor layer 143 (p⁺) in which B₂H₆ or Al is doped at a concentration of 1×10¹⁹ to 1×10²⁰/cm³ may be formed (see FIG. 3). The highly concentrated p-type semiconductor layer 143 (p⁺) may serve as a BSF layer which may enhance the electric field applied between the electrodes. After the highly doped p-type semiconductor layer 143 (p⁺), the p-type semiconductor layer 141 and the n-type semiconductor layer 142 are formed, heat treatment may be carried out for 30 to 600 seconds at 500 to 950° C. under inert gas atmosphere in order to activate the p-n junction. Like the p-type or n-type semiconductor layer 141 or 142, the highly doped p-type semiconductor layer 143 (p⁺) may also be formed of any one of Si, Si—Ge, a group III-V compound semiconductor and a group II-VI compound semiconductor. Each of the highly doped p-type semiconductor layer 143 (p⁺), the p-type semiconductor layer 141 and the n-type semiconductor layer 142 may be formed to have a thickness of 0.1 to 50 μm.

Further, a second diffusion barrier layer may be formed on the silicide layer 130 prior to the formation of the p-type semiconductor layer 141 (S704) (see FIG. 4). The second diffusion barrier layer may serve to prevent the metal from the silicide layer 130 from being diffused into the semiconductor layer 140 while the semiconductor layer 140 is formed. The second diffusion barrier layer may be formed of a silicon oxide (SiO₂) layer. The silicon oxide layer may be formed with a thickness of 1 to 10 Å by supplying TEMASi as precursor for 1 to 10 seconds and carrying out purging with argon for 1 to 10 seconds, while supplying O₃ as reaction precursor for 1 to 10 seconds at a substrate temperature of 250 to 450° C. and with a growth rate of 0.5 to 0.9 Å/cycle, or by atomic layer deposition.

After the semiconductor layer 140 is formed, a transparent electrode 150 may be formed on the semiconductor layer 140 with a thickness of 500 to 5,000 Å (S706). The transparent electrode 150 may be formed of any one of ZnO, NiO, SnO₂, ITO, GZO, IGZO, IGO, IZO and In₂O₃. When the transparent electrode 150 is formed of ZnO, it may be formed by using DEZ (diethylzinc: (C₂H₅)₂Zn) as precursor, using O₃ as reaction precursor and carrying out atomic layer deposition at 200 to 450° C. Here, the supplying time of each gas and the argon purge time may be 1 to 10 seconds, respectively.

In order to improve electric conductivity of the transparent electrode 150, it may be required to dope a dopant into the transparent electrode 150 with a content of 0.1 to 10%. For instance, when Al is doped into a ZnO transparent electrode 150 (ZnO:Al), DMAlP (dimethylaluminum isopropoxide:((CH₃)₂AlOCH(CH₃)₂) may be used as Al source. After DEZ and DMAlP are supplied to the substrate, the molecules may be adsorbed on the substrate by carrying out argon purging. Then, O₃ may be supplied so that the molecules bond with oxygen atoms, thereby forming an Al-doped ZnO:Al layer. The degree of doping may be determined either by the ratio of partial pressures of DEZ and DMAlP, or by the ratio of the time during which DEZ is supplied to the substrate and the time during which DMAlP is supplied. Alternatively, an AlOₓ (0<x<1.5, e.g. Al₂O₃) layer may be formed by supplying DMAlP only because the precursor is rich in oxygen atoms. As DMAlP is supplied to the substrate, an Al-rich layer is formed. Therefore, by repeating the process of forming a single Al₂O₃ atom layer (˜0.8 Å) up to 5 Å by supplying only DMAlP to the substrate after depositing a ZnO atomic layer with a thickness of 5 to 100 Å using DEZ and O₃, a ZnO/AlO/ . . . /ZnO/AlO composite layer may be obtained. At the temperature where this composite layer is formed, a ZnO:Al layer may be obtained from interdiffusion between the ZnO layer and the Al-rich AlO layer.

Alternatively, AlN may be formed instead of Al₂O₃ (AlOₓ) while ZnO is formed so as to form a ZnO/AlN/ZnO/AlN composite layer. In order to dope Al into ZnO, a substitutional doping by which Zn atoms are substituted by Al atoms should occur. However, normally, interstitial doping by which Al atoms are inserted between ZnO lattices due to the difference of lattice constants tends to occur with TMA (trimethylaluminum: (CH₃)₃Al). Further, whereas the leakage current of the Al₂O₃ is caused by a conduction mechanism due to the Fowler-Nordheim (F-N) tunneling effect, that of the AlN layer is caused by the Poole-Frenkel conduction mechanism. Consequently, by depositing a ZnO atomic layer (5 to 100 Å) and an AlN atomic layer (0.8 to 5 Å) at the same temperature to a total thickness of 500 to 5,000 Å using NH₃ plasma after adsorbing TMA on the substrate, the electric conductivity of the transparent electrode may be improved. For instance, the electric conductivity can be improved by at least 5% using a structure of ZnO (50 Å)/AlN (2 Å)/ . . . /ZnO (50 Å)/AlN (2 Å). Similarly, TMG (trimethylgalium: ((CH₃)₃Ga), TMI (trimethylindium: ((CH₃)₃In) or may be used to form an intermediate layer comprising a group III-V compound such as GaN, InN, etc.

In addition to Al, the dopant doped into the transparent electrode may be Ga or In. Further, a combination of Al, Ga and In may be used.

Further, when forming the transparent electrode 150, an IR reflecting layer 160 may be laminated alternatively along with the transparent electrode 150 in order to prevent temperature increase of the substrate 110. That is, as illustrated in FIG. 5A, FIG. 5B and FIG. 5C, a structure of IR reflecting layer 160/transparent electrode 150/IR reflecting layer 160 or transparent electrode 150/IR reflecting layer 160/transparent electrode 150 may be employed. The IR reflecting layer 160 may be formed of any one of Al, Au, Ag, Ru, Ir, Pt, Ni, Co, Ti, Ta and Cu. The IR reflecting layer 160 may be formed to have a thickness of 10 to 100 Å. In case of laminating to provide the structure illustrated in FIG. 5B, the thickness of the transparent electrode 150 may be about half (250 to 2,500 Å) of that in FIG. 5C. When Al is used to form the IR reflecting layer 160, it may be formed by atomic layer deposition using TMA and hydrogen plasma.

After the transparent electrode 150 is formed or after the transparent electrode 150 and the IR reflecting layer 160 are laminated alternatively, a front electrode 170 may be formed on the transparent electrode 150 or the IR reflecting layer 160 (S707). The front electrode 170 may have a comb-shaped structure (interdigital electrode), and may be formed of any one of Al, Ag, Cu, Mo and W. Further, the front electrode 170 may be formed by sputtering, silk screening of Ag paste, ink jet printing followed by firing at 450° C. for 30 minutes under N₂+H₂ gas atmosphere, as well as by electroplating or electroless plating. Normally, a back electrode should be provided at the back side of the graphite substrate. However, in an example embodiment, no additional back electrode may be required at the back side of the graphite substrate as described earlier, because the graphite substrate may serve both as a substrate and a back electrode. Still, a simple conductive pattern (not shown) may be formed for connection with an external wiring.

After the front electrode 170 is formed, a protective layer 190 may be formed on the entire surface of the substrate covering the front electrode 170 (S709). Then, the process of fabricating a solar cell according to an embodiment may be completed. The protective layer 190 may serve to protect the solar cell from external physical or chemical impact and to enhance light absorption. The protective layer 190 may be formed of SiNₓ, AlN, SiO₂, NiO, Cr₂O₃, Al₂O₃ or a combination thereof to a thickness of 1,000 to 5,000 Å. Further, a metal oxide layer 180 may be provided between the front electrode 170 and the protective layer 190 to have a thickness of 10 to 100 Å, in order to prevent deterioration of the transparent electrode 150 (S708) (see FIG. 6). The metal oxide layer 180 may be made of any one selected from Al₂O₃, NiO and TiO₂. The metal oxide layer 180 may be formed at 200 to 450° C. using Al precursor, TMA and H₂O or O₃ as reaction precursor. Supply time of the Al precursor may be 0.1 to 1 second, supply time of the reaction precursor may be 0.1 to 3 seconds, and purge time may be 1 to 5 seconds.

The present invention has been described in detail with reference to example embodiments thereof. However, it will be appreciated by those skilled in the art that changes may be made in these example embodiments without departing from the principles and spirit of the invention, the scope of which is defined in the accompanying claims and their equivalents.

What is claimed is:

1. A solar cell, comprising:
a substrate;
a semiconductor layer formed on the substrate; and
a front electrode formed on the semiconductor layer.

2. The solar cell according to claim 1, wherein the substrate is a flexible substrate having a coefficient of thermal expansion comparable to that of the semiconductor layer.

3. The solar cell according to claim 1, which further comprises a silicide layer between the substrate and the semiconductor layer.

4. The solar cell according to claim 3, which further comprises a first diffusion barrier layer between the substrate and the silicide layer.

5. The solar cell according to claim 3, which further comprises a second diffusion barrier layer between the silicide layer and the semiconductor layer.

6. The solar cell according to claim 1, wherein the semiconductor layer comprises a p-type semiconductor layer and an n-type semiconductor layer

7. The solar cell according to claim 6, wherein the semiconductor layer further comprises an intrinsic semiconductor.

8. The solar cell according to claim 6, which further comprises a highly concentrated p-type semiconductor layer including a relatively higher concentration of a p-type dopant than that of the p-type semiconductor layer below the p-type semiconductor layer.

9. The solar cell according to claim 1, which further comprises a transparent electrode between the semiconductor layer and the front electrode.

10. The solar cell according to claim 9, wherein the transparent electrode comprises a first transparent electrode.

11. The solar cell according to claim 10, wherein the first transparent electrode is made of a material selected from ZnO, NiO, SnO₂, ITO (indium tin oxide), GZO (gallium zinc oxide), IGZO (indium gallium zinc oxide), IGO (indium gallium oxide), IZO (indium zinc oxide) and In₂O₃.

12. The solar cell according to claim 9, wherein the transparent electrode comprises a combination of a first transparent electrode and a second transparent electrode, and the first transparent electrode and the second transparent electrode are laminated alternatively and repeatedly.

13. The solar cell according to claim 12, wherein the first transparent electrode is made of a material selected from ZnO, NiO, SnO₂, ITO (indium tin oxide), GZO (gallium zinc oxide), IGZO (indium gallium zinc oxide), IGO (indium gallium oxide), IZO (indium zinc oxide) and In₂O₃.

14. The solar cell according to claim 12, wherein the second transparent electrode is made of a group III-V compound.

15. The solar cell according to claim 14, wherein the group III-V compound is selected from AlN, GaN and InN.

16. The solar cell according to claim 10, wherein the first transparent electrode is doped with a dopant.

17. The solar cell according to claim 16, wherein the dopant is doped at a content of 0.1 to 10%.

18. The solar cell according to claim 16, wherein the dopant is selected from Al, In, Ga, F, and a combination thereof.

19. The solar cell according to claim 10, which further comprises an Al₂O₃ layer on the first transparent electrode, wherein the first transparent electrode and the Al₂O₃ layer are laminated alternatively and repeatedly.

20. The solar cell according to claim 19, wherein the first transparent electrode is made of ZnO.

21. The solar cell according to claim 1, which further comprises an infrared (IR) barrier layer on at least one of the top and bottom portions of the transparent electrode, wherein the transparent electrode and the IR barrier layer are laminated alternatively.

22. The solar cell according to claim 1, which further comprises a protective layer on the front electrode.

23. The solar cell according to claim 22, which further comprises an alumina layer between the front electrode and the protective layer.

24. The solar cell according to claim 3, wherein the silicide layer is made of any one selected from NiSi₂, TiSi₂, CoSi₂, MoSi₂, PdSi₂, PtSi₂, TaSi₂ and WSi₂.

25. The solar cell according to claim 4, wherein the first diffusion barrier layer comprises a refractory metal nitride layer which is made of any one selected from TiN, TaN and WN, or a refractory metal/refractory metal nitride double layer in which a refractory metal which is made of any one selected from Ti, Ta, Mo, Co and Ni and a refractory metal nitride which is made of any one selected from TiN, TaN, WN and MoN are sequentially laminated.

26. The solar cell according to claim 5, wherein the second diffusion barrier layer is made of any oxide selected from SiO₂, NiO, Al₂O₃, AgO, CuO, ZnO, In₂O₃, SnO₂, InSnO_{X}, TiO₂, HfO₂, ZrO₂, RuO₂ and Ta₂O₅, or a metal-silicate formed by atomic layer deposition.

27. The solar cell according to claim 21, wherein the IR barrier layer is made of any one selected from Al, Au, Ag, Ru, Ir, Pt, Ni, Co, Ti, Ta, and Cu.

28. The solar cell according to claim 22, wherein the protective layer is made of SiNₓ, AlN, SiO₂, NiO, Cr₂O₃, Al₂O₃ or a combination thereof.

29. The solar cell according to claim 1, wherein the substrate has a thickness of 0.005 to 0.125 inch.

30. The solar cell according to claim 1, wherein the semiconductor layer is made of Si, SiGe, a group III-V compound semiconductor, a group II-VI compound semiconductor or a combination thereof.

31. A method for fabricating a solar cell, comprising:
(a) providing a substrate;
(b) forming a semiconductor layer on the substrate; and
(c) forming a front electrode on the semiconductor layer.

32. The method for fabricating a solar cell according to claim 31, which further comprises a step of: (a)-2 forming a silicide layer on the substrate, prior to the step (b).

33. The method for fabricating a solar cell according to claim 32, which further comprises a step of: (a)-1 forming a first diffusion barrier layer on the substrate, prior to the step (a)-2.

34. The method for fabricating a solar cell according to claim 33, which further comprises a step of: (a)-3 forming a second diffusion barrier layer on the silicide layer, prior to the step (b).

35. The method for fabricating a solar cell according to claim 34, wherein the step (b) comprises a first process of forming a p-type semiconductor layer and a second process of forming an n-type semiconductor layer, wherein either of the first process or the second process may be carried out first

36. The method for fabricating a solar cell according to claim 35, wherein the step (b) further comprises a process of forming an intrinsic semiconductor layer which is carried out between the first process and the second process.

37. The method for fabricating a solar cell according to claim 35, wherein the step (b) further comprises forming a highly doped p-type semiconductor layer including a relatively higher doping of a p-type dopant than that of the p-type semiconductor layer prior to forming the p-type semiconductor layer.

38. The method for fabricating a solar cell according to claim 34, which further comprises a step of: (b)-1 forming a transparent electrode on the semiconductor layer, prior to the step (c).

39. The method for fabricating a solar cell according to claim 38, wherein the step (b)-1 comprises forming a first transparent electrode on the semiconductor layer.

40. The method for fabricating a solar cell according to claim 39, wherein the first transparent electrode is made of any one selected from ZnO, NiO, SnO₂, ITO, GZO, IGZO, IGO, IZO and In₂O₃.

41. The method for fabricating a solar cell according to claim 39, wherein the step (b)-1 comprises a combination of forming a first transparent electrode on the semiconductor layer and forming a second transparent electrode on the first transparent electrode.

42. The method for fabricating a solar cell according to claim 41, wherein the first transparent electrode is made of any one selected from ZnO, NiO, SnO₂, ITO, GZO, IGZO, IGO, IZO and In₂O₃.

43. The method for fabricating a solar cell according to claim 41, wherein the second transparent electrode is made of a group III-V compound.

44. The method for fabricating a solar cell according to claim 43, wherein the group III-V compound is any one selected from AlN, GaN and InN.

45. The method for fabricating a solar cell according to claim 41, wherein the first transparent electrode and the second transparent electrode are formed by atomic layer deposition.

46. The method for fabricating a solar cell according to claim 39, wherein the first transparent electrode is doped with a dopant.

47. The method for fabricating a solar cell according to claim 46, wherein the dopant is doped at a content of 0.1 to 10%.

48. The method for fabricating a solar cell according to claim 41, wherein the second transparent electrode is doped with a dopant.

49. The method for fabricating a solar cell according to claim 48, wherein the dopant is doped at a content of 0.1 to 10%.

50. The method for fabricating a solar cell according to claim 39, which further comprises forming an Al₂O₃ layer on the first transparent electrode.

51. The method for fabricating a solar cell according to claim 50, wherein the Al₂O₃ is formed using TMA (Trimethylaluminum: (CH₃)₃Al), or DMAlP (dimethylaluminum isopropoxide: (CH₃)₂AlOCH(CH₃)₂).

52. The method for fabricating a solar cell according to claim 38, wherein, in the step (b)-1, the transparent electrode and an IR barrier layer which is provided on at least one of the top and bottom portions of the transparent electrode are laminated alternatively.

53. The method for fabricating a solar cell according to claim 31, which further comprises a step of: (c)-2 forming a protective layer on the front electrode, following the step (c).

54. The method for fabricating a solar cell according to claim 53, which further comprises a step of: (c)-1 forming a metal oxide layer made of any one selected from Al₂O₃, NiO, TiO₂ on the front electrode, prior to the step (c)-2.

55. The method for fabricating a solar cell according to claim 32, wherein the step (a)-2 comprises:
depositing a metallic layer formed by atomic layer deposition on the substrate; and
depositing silicon on the metallic layer to form a polycrystalline silicide layer comprising a metal-silicon combination.

56. The method for fabricating a solar cell according to claim 55, wherein the metallic layer is made of any one of Ni, Al, Ti, Co, Mo, Pd, Pt, Ta, W, AlO_{X}, NiO_{X}, CoO_{X}, TiO_{X}, TaO_{X}, NiSi, TiSi, CoSi, MoSi, PdSi, PtSi, TaSi, and WSi.

57. The method for fabricating a solar cell according to claim 56, wherein the polycrystalline silicide layer is made of any one of NiSi₂, TiSi₂, CoSi₂, MoSi₂, PdSi₂, PtSi₂, TaSi₂ and WSi₂.

58. The method for fabricating a solar cell according to claim 33, wherein the first diffusion barrier layer is formed as a refractory metal nitride layer which is made of any one selected from TiN, TaN and WN, or a refractory metal/refractory metal nitride double layer in which a refractory metal which is made of any one selected from Ti, Ta, Mo, Co and Ni and a refractory metal nitride which is made of any one selected from TiN, TaN, WN and MoN are sequentially laminated.

59. The method for fabricating a solar cell according to claim 41, wherein the second diffusion barrier layer is made of any oxide selected from SiO₂, NiO, Al₂O₃, AgO, CuO, ZnO, In₂O₃, SnO₂, InSnO_{X}, TiO₂, HfO₂, ZrO₂, RuO₂ and Ta₂O₅, or a metal-silicate formed by atomic layer deposition.

60. The method for fabricating a solar cell according to claim 52, wherein the IR barrier layer is made of any one selected from Al, Au, Ag, Ru, Ir, Pt, Ni, Co, Ti, Ta, and Cu.

61. The method for fabricating a solar cell according to claim 53, wherein the protective layer is made of SiNₓ, AlN, SiO₂, NiO, Cr₂O₃, Al₂O₃ or a combination thereof.

62. The method for fabricating a solar cell according to claim 31, wherein the semiconductor layer is made of Si, SiGe, a group III-V compound semiconductor, a group II-VI compound semiconductor or a combination thereof.

63. The method for fabricating a solar cell according to claim 32, wherein the step (a)-2 comprises:
depositing a metallic layer formed by atomic layer deposition on the substrate; and
depositing a semiconductor material of any one of Si and SiGe on the metallic layer to form a polycrystalline semiconductor layer comprising a metal-semiconductor combination.
